(19) United States
(12) Patent Application Publication
(10) Pub. No.: US 2008/0003792 A1
(43) Pub. Date: Jan. 3, 2008

(54) Method for forming a gate of a semiconductor device

(76) Inventor: Kwang Kee Chae, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/647,865

(22) Filed: Dec. 29, 2006

(30) Foreign Application Priority Data
Jun. 30, 2006 (KR) 10-2006-0061584

(51) Int. Cl. H01L 21/467

(52) U.S. Cl. 438/592; 438/735

(57) ABSTRACT

A gate of a semiconductor device is formed by forming sequentially a gate insulation layer, a polysilicon layer, metal based layer and a hard mask on a semiconductor substrate; etching primarily the metal based layer and a partial thickness of the polysilicon layer using the hard mask as an etch mask; cleaning primarily surfaces of the etched metal based layer and polysilicon layer with an HF-containing solution; and cleaning secondarily the primarily cleaned surfaces using ozone.

### CROSS-REFERENCE TO RELATED APPLICATIONS

The present application claims priority to Korean patent application number 10-2006-0061584 filed on Jun. 30, 2006, which is incorporated herein by reference in its entirety.

### BACKGROUND OF THE INVENTION

The present invention relates to a method for forming a gate of a semiconductor device, and more particularly, to a cleaning method which is executed after etching of a metal based layer for a gate.

As the high integration of a semiconductor device proceeds, the gate line width is decreased due to reduction of cell size. Therefore, various technologies for forming a gate capable of realizing low resistance in a fine line width have been researched and developed. Further, in order to realize low resistance, tungsten having very low resistance has been used as a gate material.

FIGS. 1A through 1C are cross-sectional views illustrating the process steps of a conventional method for forming a gate using tungsten as a gate material.

Referring to FIG. 1A, after a gate insulation layer 102 is formed on a semiconductor substrate 100, a polysilicon layer 104, a tungsten silicide layer 106, a tungsten nitride layer 108 and a tungsten layer 110 are sequentially deposited on the gate insulation layer 102. A hard mask 112, which defines a gate forming area, is formed on the tungsten layer 110. The tungsten layer 110, the tungsten nitride layer 108 and the tungsten silicide layer 106 are etched using the hard mask 112 as an etch mask. At this time, when etching the tungsten silicide layer 106, a partial thickness of the polysilicon layer 104 is etched as well.

In order to remove polymers and organics produced on the surfaces of the etched layers 110, 108, 106 and 104, the resultant substrate is primarily cleaned using an SPM (sulfuric acid peroxide mixture) solution. The SPM solution is a solution in which sulfuric acid and hydrogen peroxide is mixed in a ratio of 4:1. The resultant substrate, which is primarily cleaned, is secondarily cleaned using an HF solution.

Referring to FIG. 1B, in order to prevent the side surfaces of the tungsten layer 110, the tungsten nitride layer 108 and the tungsten silicide layer 106 from being oxidized in a subsequent thermal process, an oxidation prevention capping layer 114 comprising a nitride layer is deposited on the primarily etched tungsten layer 110, tungsten nitride layer 108, tungsten silicide layer 106 and polysilicon layer 104 including the hard mask 112.

Referring to FIG. 1C, the polysilicon layer 104 and the gate insulation layer 102, which are not etched by the primary etching, are secondarily etched using the oxidation prevention capping layer 114 and the hard mask 112 as an etch mask, and through this, a gate 120 is formed.

However, the conventional method for forming a gate has problems as described below.

In the conventional art, after the tungsten layer 110, the tungsten nitride layer 108 and the tungsten silicide layer 106 are primarily etched, in order to remove the polymers and organics produced on the surface of the etched layers, the first cleaning process is conducted using the SPM solution. In the first cleaning process using the SPM solution, as shown in FIG. 2A, a phenomenon occurs in which the tungsten nitride layer 108 is lost by the SPM solution, and as a result, device characteristic deterioration, such as an increase in gate resistance, is caused.

Also, in the conventional art, after the first cleaning process is conducted using the SPM solution, secondary cleaning is conducted using an HF solution. In this regard, because the surface of the polysilicon layer 104, which is partially etched by the primary etching, becomes hydrophobic under the influence of the HF solution, when subsequently depositing the oxidation prevention capping layer 114, as shown in FIG. 2B, a phenomenon occurs in which the oxidation prevention layer 114 is deposited relatively thinly on the hydrophobic portion of the polysilicon layer 104. As a result, a gate pattern defect can be caused, and the yield of a semiconductor device is decreased.

### SUMMARY OF THE INVENTION

An embodiment of the present invention is directed to a method for forming a gate of a semiconductor device which can prevent the occurrence of a defect in the cleaning process for removing polymers and organics.

In one embodiment, a method for forming a gate of a semiconductor device comprises the steps of forming sequentially a gate insulation layer, a polysilicon layer, a metal silicide layer, a metal nitride layer, a metal layer and a hard mask on a semiconductor substrate; etching primarily the metal layer, the metal nitride layer, the metal silicide layer, and a partial thickness of the polysilicon layer using the hard mask as an etch mask; cleaning primarily the resultant substrate using an HF-containing solution to remove polymers and organics produced on surfaces of the etched metal layer, metal nitride layer, metal silicide layer and polysilicon layer; cleaning secondarily the primarily cleaned resultant substrate using ozone so that the surface of the polysilicon layer becomes hydrophilic; forming an oxidation prevention capping layer on the etched metal layer, metal nitride layer, metal silicide layer, and polysilicon layer including the hard mask to a uniform thickness; and etching the polysilicon layer and the gate insulation layer using the oxidation prevention capping layer and the hard mask as an etch mask. The metal layer, metal nitride layer and metal silicide layer together form a metal based layer.

The metal layer may comprise a tungsten layer, the metal nitride layer may comprise a tungsten nitride layer, and the metal silicide layer may comprise a tungsten silicide layer.

The primary cleaning step using the HF-containing solution is conducted at a temperature of 20˜50° C.

The secondary cleaning step using the ozone is conducted at a temperature of 20˜5° C. with an ozone concentration of 50˜500 ppm.

The secondary cleaning step using the ozone is conducted as a spin type or a dipping type cleaning.

The spin type cleaning is conducted in a manner such that a mixture of DIW and ozone is injected, or ozone is separately injected while DIW is injected.

The dipping type cleaning is conducted using a mixed solution of DIW and ozone, or a mixed solution of an HF-containing solution and ozone.

The capping layer is formed as a kind of a nitride layer.

### BRIEF DESCRIPTION OF THE DRAWINGS

FIGS. 1A through 1C are cross-sectional views illustrating the process steps of a conventional method for forming a gate of a semiconductor device.

FIGS. 2A and 2B are photographs explaining the problems of the conventional art.

FIGS. 3A through 3E are cross-sectional views illustrating the process steps of a method for forming a gate of a semiconductor device in accordance with an embodiment of the present invention.

FIGS. 4A and 4B are photographs explaining the effects according to an embodiment of the present invention.

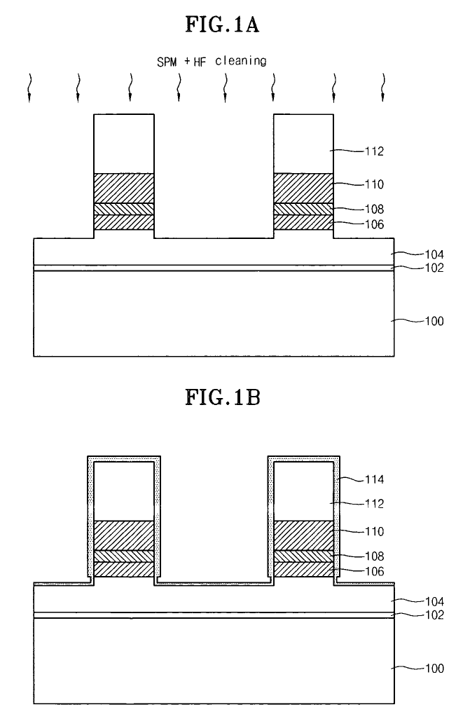

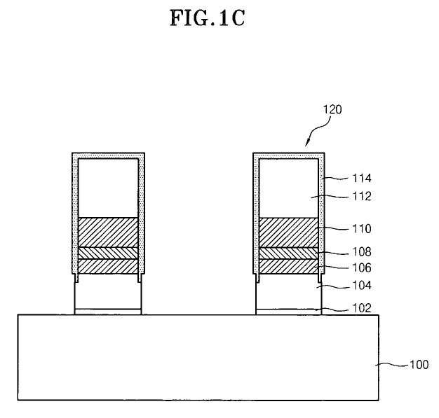

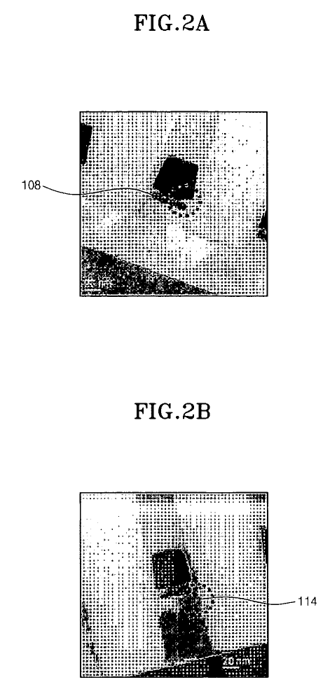

### DESCRIPTION OF SPECIFIC EMBODIMENTS

In an embodiment of the present invention, a metal gate is formed by etching a metal based layer, a polysilicon layer, and a gate insulation layer. Preferably, the metal based layer includes a metal layer, a metal nitride layer and a metal silicide layer. In particular, in an embodiment of the present invention, after the metal layer, the metal nitride layer, the metal silicide layer and a partial thickness of the polysilicon layer are primarily etched, in order to remove polymers and organics produced on the surfaces of the etched layers, cleaning is sequentially conducted using an HF-containing solution and ozone (O₃).

Therefore, in an embodiment of the present invention, as the primary cleaning process is conducted using the HF-containing solution, the polymers and organics can be removed, and as a consequence, it is possible to prevent the occurrence of a defect in which the metal nitride layer is lost. Further, in an embodiment of the present invention, after the primary cleaning, as a secondary cleaning is conducted using ozone (O₃), the surface of the etched polysilicon layer becomes hydrophilic. Thus, when depositing an insulation layer as an oxidation prevention layer for preventing a subsequently formed metal layer from being oxidized, the deposition thickness of the insulation layer on the polysilicon layer can be made uniform, so it is possible to prevent a defect from occurring in a gate pattern.

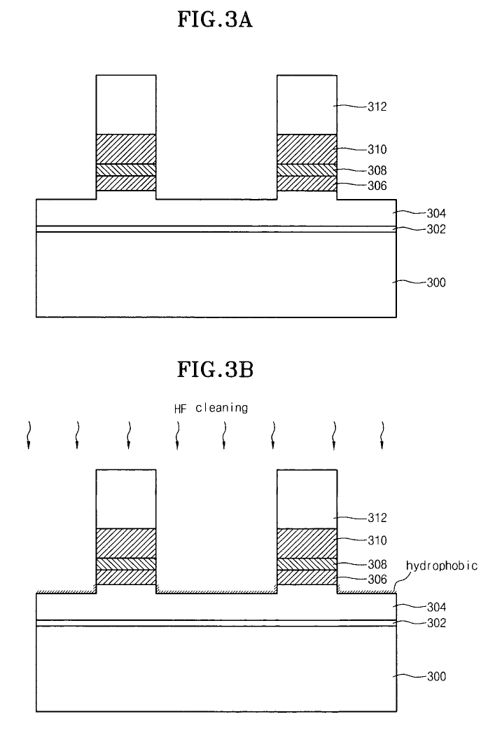

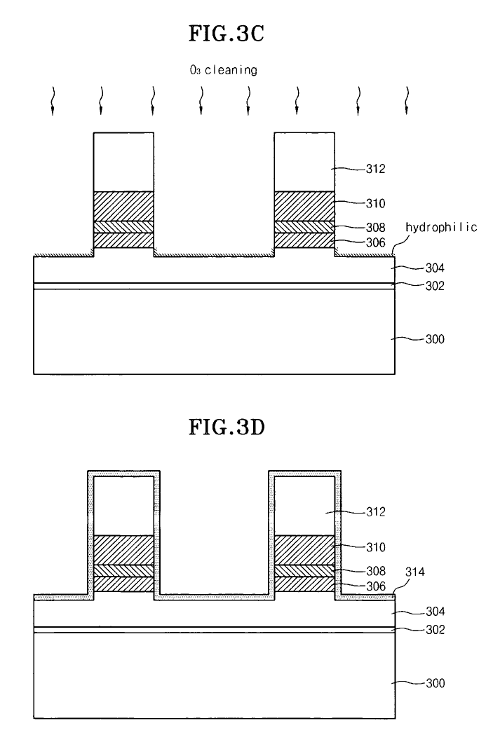

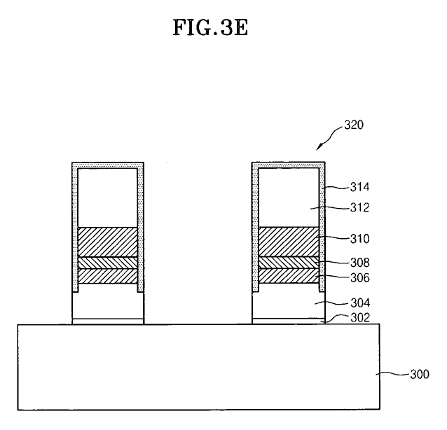

Hereafter, a method for forming a gate of a semiconductor device in accordance with an embodiment of the present invention will be described with reference to FIGS. 3A through 3E.

Referring to FIG. 3A, a gate insulation layer 302 is formed on a semiconductor substrate 300. A polysilicon layer 304 is deposited on the gate insulation layer 302. A tungsten silicide layer 306 is deposited on the polysilicon layer 304 as a metal silicide layer for an ohmic contact. A tungsten nitride layer 308 is deposited on the tungsten silicide layer 306 as a metal nitride layer for diffusion prevention. A tungsten layer 310 is deposited on the tungsten nitride layer 308 as a gate metal layer.

A nitride layer is deposited on the tungsten layer 310 as a hard mask layer. After a photoresist pattern (not shown) for defining a gate forming area is formed on the nitride layer, by etching the nitride layer using the photoresist pattern as an etch mask, a hard mask 312 is formed. The photoresist pattern is removed. Using the hard mask 312 as an etch mask, the tungsten layer 310, the tungsten nitride layer 308, and the tungsten silicide layer 306 are primarily etched. At this time, a partial thickness of the polysilicon layer 304, which is exposed due to etching of the tungsten silicide layer 306, is also etched.

Referring to FIG. 3B, in order to remove the polymers and organics which are produced on the surfaces of the etched polysilicon layer 304, tungsten silicide layer 306, tungsten nitride layer 308 and tungsten layer 310, a primary cleaning process is conducted for the resultant substrate which has undergone the primary etching. The primary cleaning process is conducted at a temperature of 20˜50° C. using an HF-containing solution, that is, an HF solution or a BOE (NH₄F+HF) solution. As a result of the primary cleaning process using the HF-containing solution, the surface of the etched polysilicon layer 304 becomes hydrophobic.

Here, in an embodiment of the present invention, because the primary cleaning process is conducted using the HF-containing solution, the polymers and the organics can be removed, and it is possible to prevent the tungsten nitride layer 308 from being lost in the primary cleaning process. In the conventional art, since the primary cleaning process is conducted using an SPM solution, while the polymers and organics can be removed, the loss of the tungsten nitride layer is caused by the SPM solution during cleaning. In contrast, in the present invention, since the primary cleaning process is conducted using the HF-containing solution which allows the removal of the polymers and organics and does not cause damage to the tungsten nitride layer, only the polymers and organics can be stably removed without experiencing the loss of the tungsten nitride layer.

Referring to FIG. 3C, a secondary cleaning process is conducted for the resultant substrate having undergone the primary cleaning process using ozone (O₃). The secondary cleaning process using ozone is conducted at a temperature of 20˜50° C. with an ozone concentration no greater than 500 ppm, preferably, of 50˜500 ppm. Also, the secondary cleaning process using the ozone is conducted in a spin type or a dipping type cleaner. In the spin type, the injection of ozone is implemented in a manner such that DIW (deionized water) and ozone are mixed with each other and a mixture thereof is injected, or ozone is separately injected while DIW is injected. In the dipping type, a mixed solution of DIW and ozone or a mixed solution of an HF-containing solution and ozone is used.

Here, as the result of the secondary cleaning process using ozone, the surface of the polysilicon layer 304, which has become hydrophobic as the result of the primary cleaning process, becomes hydrophilic. Accordingly, in the present invention, since the surface of the polysilicon layer 304 becomes hydrophilic, when subsequently depositing an oxidation prevention capping layer, a deposition thickness thereof on the polysilicon layer 304 can be increased, and therefore, the deposition thickness of the oxidation prevention capping layer can be made uniform. As a consequence, in an embodiment of the present invention, since the deposition thickness of the oxidation prevention capping layer can be made uniform, a defect is not caused in a gate pattern which is finally obtained.

In the conventional art, because the secondary cleaning process is conducted using the HF-containing solution, the surface of the polysilicon layer, which is obtained as the result of the secondary cleaning process, becomes hydrophobic. Thus, when subsequently depositing the oxidation prevention capping layer, the insulation layer is deposited relatively thinly on the portions of the polysilicon layer which have become hydrophobic, and a contour is obtained in which the sidewall portions of the polysilicon layer are recessed inward. Accordingly, due to the oxidation prevention capping layer deposited to a non-uniform thickness, a defect is caused in the pattern of the finally obtained gate.

In contrast, in an embodiment of the present invention, since the secondary cleaning process is conducted for the resultant substrate having undergone the primary cleaning process using ozone, the surface of the polysilicon layer having undergone the secondary cleaning process becomes hydrophilic. As a consequence, when subsequently depositing the oxidation prevention capping layer, since the deposition thickness of the oxidation prevention capping layer on the hydrophilic portions of the polysilicon layer can be increased in comparison with the conventional art, the overall deposition thickness of the oxidation prevention capping layer can be made uniform, and therefore, a gate pattern defect due to the non-uniform deposition thickness of the oxidation prevention layer is not caused.

Referring to FIG. 3D, the oxidation prevention capping layer 314 comprising a nitride-based material is deposited on the primarily etched tungsten layer 310, tungsten nitride layer 308, tungsten silicide layer 306 and polysilicon layer 304 including the hard mask 312. At this time, as described above, since the surface of the etched polysilicon layer 304 becomes hydrophilic due to the secondary cleaning process using ozone, the oxidation prevention capping layer 314 is deposited to a uniform thickness.

Referring to FIG. 3E, by secondarily etching the oxidation prevention capping layer 314 comprising a nitride-based material, the polysilicon layer 304 and the gate insulation layer 302, a gate 320 is formed. At this time, because the oxidation prevention capping layer 314 is formed on the sidewalls of the tungsten layer 310, the tungsten nitride layer 308 and the tungsten silicide layer 306, when subsequently conducting a thermal process, the oxidation prevention capping layer 314 serves to prevent the above layers from being oxidized.

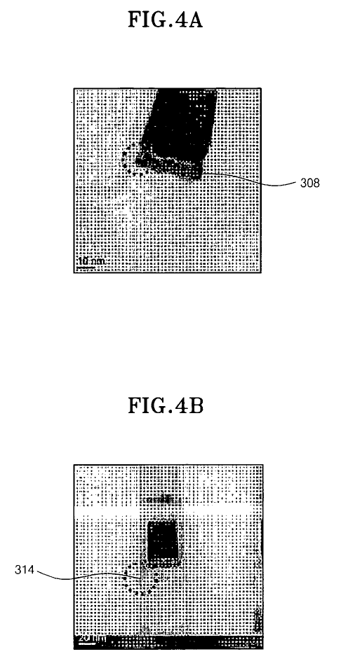

As is apparent from the above description, in the present invention, as the cleaning process for removing polymers and organics is conducted using the HF-containing solution, as shown in FIG. 4A, it is possible to prevent the metal nitride layer 308 as a diffusion prevention layer from being lost in the cleaning process. Further, in the present invention, after the cleaning process using the HF-containing solution is conducted, by conducting another cleaning process using ozone (O₃), the surface of the polysilicon layer becomes hydrophilic. Therefore, as shown in FIG. 4B, the deposition thickness of the oxidation prevention capping layer 314 can be made uniform, and a stable gate pattern can be formed. Therefore, according to the present invention, a desired metal gate characteristic can be attained, and the yield of a semiconductor device can be increased.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for forming a gate of a semiconductor device, comprising the steps of:
forming sequentially a gate insulation layer, a polysilicon layer, a metal based layer and a hard mask on a semiconductor substrate;
etching primarily the metal based layer and a partial thickness of the polysilicon layer using the hard mask as an etch mask;
cleaning primarily surfaces of the etched metal based layer and polysilicon layer with an HF-containing solution;
cleaning secondarily the primarily cleaned surfaces using ozone;
forming a capping layer on the etched metal based layer and polysilicon layer including the hard; and
etching the polysilicon layer and the gate insulation layer using the capping layer and the hard mask as an etch mask.

2. The method according to claim 1, wherein the metal based layer comprises sequentially stacked layers of metal silicide, metal nitride and metal.

3. The method according to claim 2, wherein the metal layer comprises a tungsten layer.

4. The method according to claim 2, wherein the metal nitride layer comprises a tungsten nitride layer.

5. The method according to claim 2, wherein the metal silicide layer comprises a tungsten silicide layer.

6. The method according to claim 1, wherein the primary cleaning step using the HF-containing solution is conducted at a temperature of 20˜50° C.

7. The method according to claim 1, wherein the secondary cleaning step using the ozone is conducted at a temperature of 20˜50° C. with an ozone concentration of 50˜500 ppm.

8. The method according to claim 1, wherein the secondary cleaning step using the ozone is selected from the group consisting of spin type cleaning and dipping type cleaning.

9. The method according to claim 8, wherein the spin type cleaning is conducted in a manner such that a mixture of DIW and ozone is injected.

10. The method according to claim 8, wherein the spin type cleaning is conducted in a manner such that ozone is separately injected while DIW is injected.

11. The method according to claim 8, wherein the dipping type cleaning is conducted using a mixed solution of DIW and ozone.

12. The method according to claim 8, wherein the dipping type cleaning is conducted using a mixed solution of an HF-containing solution and ozone.

13. The method according to claim 1, wherein the capping layer is formed as a kind of a nitride layer.
